(19) United States
(12) Patent Application Publication
(10) Pub. No.: US 2026/0206550 A1
(43) Pub. Date: Jul. 16, 2026

(54) SUBSTRATE MANUFACTURING METHOD AND SUBSTRATE

(71) Applicant: DISCO CORPORATION, Tokyo (JP)

(72) Inventors: Maho HIRAKAWA, Tokyo (JP); Tomoki YOSHINO, Tokyo (JP); Mami SAEKI, Tokyo (JP)

(21) Appl. No.: 19/381,227

(22) Filed: Nov. 6, 2025

(30) Foreign Application Priority Data
Nov. 20, 2024 (JP) 2024-202459

(51) Int. Cl. H01L 21/02; H01L 21/304

(52) U.S. Cl. CPC H10P 90/128; H10P 52/00

(57) ABSTRACT

A substrate manufacturing method includes: chamfering an outer peripheral portion of the substrate, which is a boundary between the main surface and the side surface, so as to form at least one of an inclined surface or a curved surface; and polishing the main surface, and the chamfering includes forming, at the outer peripheral portion of the substrate, a first chamfered portion by forming an inclined surface or by forming a curved surface as defined herein, and forming a second chamfered portion by forming an inclined surface or by forming a curved surface as defined herein.

### CROSS-REFERENCE TO RELATED APPLICATIONS

This application is based on and claims priority under 35 USC 119 from Japanese Patent Application No. 2024-202459 filed on Nov. 20, 2024, the contents of which are incorporated herein by reference.

### TECHNICAL FIELD

The present disclosure relates to a substrate manufacturing method and a substrate.

### BACKGROUND ART

In a process of polishing a wafer when manufacturing a semiconductor wafer, so-called chemical mechanical polishing (CMP) is performed in which polishing is performed by causing slurry to enter between a workpiece on a holding table and a polishing pad. In such a polishing process, an amount of work applied to an outer peripheral portion of the wafer after polishing is larger than that applied to a central portion, which may thus cause a thickness of the outer peripheral portion to be thinner, i.e., so-called outer peripheral sag. Therefore, in a manufacturing method of a semiconductor wafer described in Patent Literature 1, a chamfered portion is provided in an outer peripheral portion of a wafer in order to reduce the outer peripheral sag and make a wafer thickness after polishing uniform.

Patent Literature 1: JP2012-129416A

### SUMMARY OF INVENTION

In a polishing step performed by the chemical mechanical polishing described above, a polishing rate indicating a polishing amount per unit time may vary depending on hardness of the polishing pad and a size of the chamfered portion. For example, when the hardness of the polishing pad is high and an inclined angle of the chamfered portion is relatively large, polishing of the outer peripheral portion of the wafer is dominant as compared with the central portion of the wafer, and the polishing rate of the central portion may decrease. In addition, for example, when the inclined angle of the chamfered portion is reduced in accordance with a polishing pad with high hardness, a chamfering shape defined by the semiconductor equipment and materials international (SEMI) standard may not be satisfied.

The disclosure provides a substrate manufacturing method capable of reducing a decrease or variation in a polishing rate while conforming to a chamfering shape defined by a standard, and a substrate.

According to an aspect of the disclosure, there is provided a method of manufacturing a substrate including a main surface and a side surface, the method including:
a chamfering step of chamfering an outer peripheral portion of the substrate, which is a boundary between the main surface and the side surface, so as to form at least one of an inclined surface or a curved surface; and
a polishing step of polishing the main surface, in which
the chamfering step includes
a first chamfering step of forming, at the outer peripheral portion of the substrate, a first chamfered portion by forming an inclined surface so that the inclined surface is in contact with the main surface and makes a first inclined angle relative to the main surface, or by forming a curved surface so that the curved surface is in contact with the main surface and that an angle between the main surface and a tangent line drawn from a contact point between the curved surface and the main surface is a first inclined angle, and
a second chamfering step of forming a second chamfered portion by forming an inclined surface so that the inclined surface is in contact with the first chamfered portion and the side surface and makes, relative to the main surface, a second inclined angle larger than the first inclined angle, or by forming a curved surface so that the curved surface is in contact with the first chamfered portion and the side surface and that an angle between the main surface and a tangent line drawn from a contact point between the curved surface and the first chamfered portion is a second inclined angle larger than the first inclined angle.

According to another aspect of the present disclosure, there is provided a substrate having a main surface and a side surface, including:
a chamfered portion having at least one of an inclined surface or a curved surface formed on an outer peripheral portion of the substrate, which is a boundary between the main surface and the side surface, in which
the chamfered portion includes
a first chamfered portion configured to form, at the outer peripheral portion of the substrate, an inclined surface so that the inclined surface is in contact with the main surface and makes a first inclined angle relative to the main surface, or form a curved surface so that the curved surface is in contact with the main surface and that an angle between the main surface and a tangent line drawn from a contact point between the curved surface and the main surface is a first inclined angle, and
a second chamfered portion configured to form an inclined surface so that the inclined surface is in contact with the first chamfered portion and the side surface and makes, relative to the main surface, a second inclined angle larger than the first inclined angle, or form a curved surface so that the curved surface is in contact with the first chamfered portion and the side surface and that an angle between the main surface and a tangent line drawn from a contact point between the curved surface and the first chamfered portion is a second inclined angle larger than the first inclined angle.

### BRIEF DESCRIPTION OF DRAWINGS

FIG. 1 is an enlarged diagram of the vicinity of an outer peripheral portion 2 of a substrate 1 and illustrates an example of a chamfered portion 3.

FIGS. 2A, 2B, and 2C are diagrams illustrating another example of the chamfered portion 3.

FIG. 3 is a flowchart illustrating an example of processing of a manufacturing method of the substrate 1 according to an embodiment.

FIG. 4 is a block diagram illustrating an example of a manufacturing device 10 for the substrate 1.

FIG. 5 is a diagram illustrating an example of a first laser processing device 20a (second laser processing device 20b).

FIG. 6 is a diagram illustrating an example of a state in which a laser beam is applied from a front surface 100a of an ingot 100.

FIG. 7 is a diagram illustrating an example of a peeling device 40.

FIG. 8 is a diagram illustrating a modification of the peeling device 40.

FIG. 9 is a perspective view illustrating an example of a grinding device 60.

FIGS. 10A and 10B are diagrams illustrating an example of a chamfering step S40.

FIG. 11 is a diagram illustrating a relation between an inclined angle and a polishing rate.

FIG. 12 is an enlarged diagram of the vicinity of the chamfered portion 3.

FIG. 13 is a diagram illustrating a relation between a compressive load and a sinking amount of the polishing pad.

FIG. 14 is a diagram illustrating an example of a polishing device 80.

FIG. 15 is a diagram in which polishing rates according to the embodiment and according to an example in the conventional art are compared.

FIGS. 16A and 16B are diagrams illustrating another example of the chamfering step S40.

### DESCRIPTION OF EMBODIMENTS

Hereinafter, a substrate manufacturing method and a substrate according to an embodiment of the disclosure will be described with reference to the drawings.

In the following description, an X-axis direction is a direction on a horizontal plane. A Y-axis direction is a direction orthogonal to the X-axis direction on the horizontal plane. A Z-axis direction is a direction orthogonal to the X-axis direction and the Y-axis direction.

### Substrate

First, the configuration of the substrate 1 will be described. The substrate 1 is, for example, substantially disk-shaped semiconductor device wafers, optical device wafers, or other wafers with substrates made of silicon (Si), silicon carbide (SiC), gallium nitride (GaN), or gallium arsenide (GaAs).

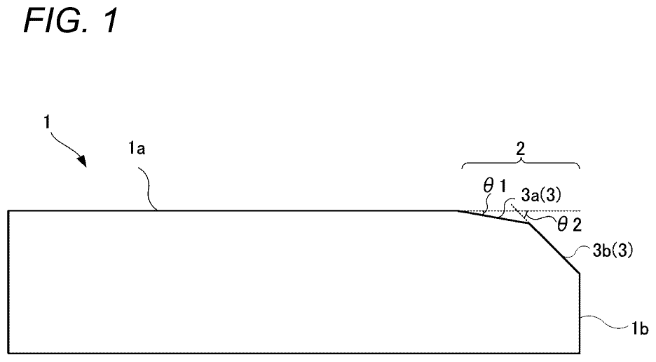

FIG. 1 is an enlarged diagram of the vicinity of the outer peripheral portion 2 of the substrate 1. The substrate 1 includes a main surface 1a and a side surface 1b. The main surface 1a is a surface on which processing such as polishing or grinding is performed, and is, for example, a front surface or a back surface of the substrate 1. In the example illustrated in FIG. 1, the front surface of the substrate 1 is illustrated on an upper side, and the back surface of the substrate 1 is illustrated on a lower side. On the front surface of the substrate 1, for example, a plurality of devices (not illustrated) such as an integrated circuit (IC) and a large scale integration (LSI) are formed in a region partitioned and formed in a lattice shape. The substrate 1 may be a so-called bare wafer, which does not have any devices such as IC or LSI formed on the front surface of the substrate. The side surface 1b is a surface in a thickness direction of the substrate 1 at an outer peripheral end of the substrate 1. The outer peripheral portion 2 indicating a boundary between the main surface 1a and the side surface 1b is chamfered, and a chamfering shape is the chamfered portion 3 having an inclined surface or a curved surface. In the example illustrated in FIG. 1, as an example, the chamfered portion 3 in which the chamfering shape is an inclined surface is illustrated. In the embodiment, as illustrated in FIG. 1, the chamfered portion 3 is chamfered in two stages between the main surface 1a and the side surface 1b.

Specifically, the chamfered portion 3 includes a first chamfered portion 3a and a second chamfered portion 3b. In the outer peripheral portion 2 of the substrate 1, the first chamfered portion 3a is formed with an inclined surface that is in contact with the main surface 1a and forms an angle, which is a first inclined angle θ1 with the main surface 1a. Since the first chamfered portion 3a is in contact with the main surface 1a, the first chamfered portion 3a is polished together with the main surface 1a. The second chamfered portion 3b is formed with an inclined surface that is in contact with the first chamfered portion 3a and the side surface 1b and forms a second inclined angle θ2 with the main surface 1a that is larger than the first inclined angle θ1. Here, the first inclined angle θ1 is an angle capable of improving a polishing rate (hereinafter, referred to as a “polishing rate”) which is a polishing amount per unit time when polishing the main surface 1a of the substrate 1, and may be determined based on, for example, an experiment. The second inclined angle θ2 is set to, for example, an angle in a predetermined angle range based on a SEMI standard, and is set to an angle capable of reducing outer peripheral sag, edge chipping of the substrate 1, and the like during polishing. Specific processing for forming the chamfered portion 3 will be described later in a substrate manufacturing method.

As described above, in the embodiment, the chamfered portion 3 is formed in two stages of the first chamfered portion 3a having the first inclined angle θ1 and the second chamfered portion 3b having the second inclined angle θ2 larger than the first inclined angle θ1. Accordingly, the first inclined angle θ1 of the first chamfered portion 3a to be polished can be set to an inclined angle capable of improving the polishing rate while satisfying the inclined angle (that is, a chamfer angle) based on the SEMI standard as the entire chamfered portion. In addition, since the second inclined angle θ2 can be set to any angle as long as the angle is within a predetermined angle range defined in the SEMI standard, for example, the second inclined angle θ2 can be set to an angle according to various requests such as an angle capable of reducing the outer peripheral sag during polishing described above or an angle capable of reducing the edge chipping.

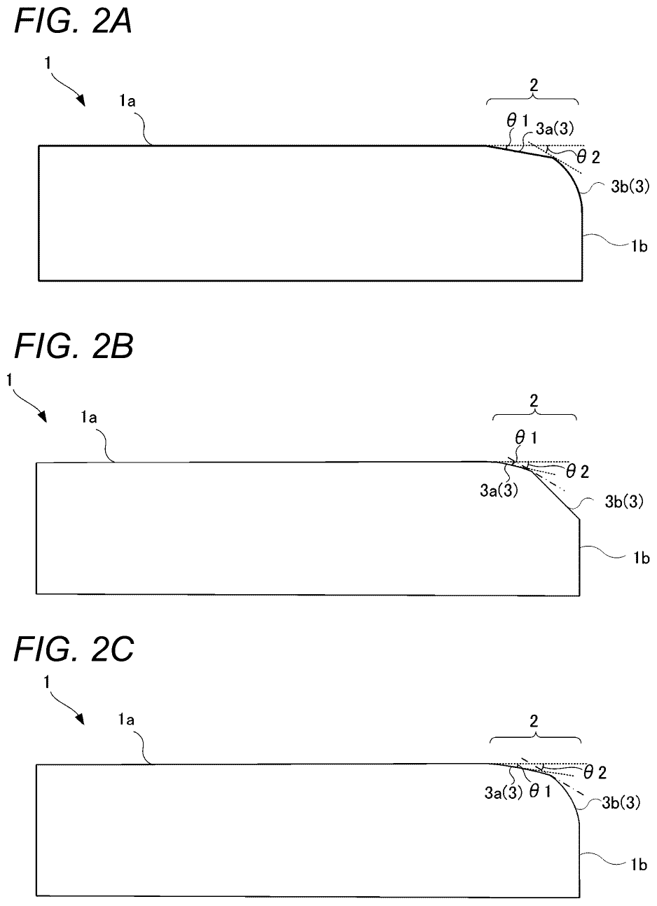

As described above, in addition to the inclined surface, the chamfered portion 3 may be formed by a curved surface or may be formed by an inclined surface and a curved surface. FIGS. 2A, 2B, and 2C illustrate other examples of the chamfered portion 3. FIG. 2A illustrates an example in which the first chamfered portion 3a is formed by an inclined surface and the second chamfered portion 3b is formed by a curved surface. In this case, the second inclined angle θ2 about the second chamfered portion 3b can be defined as “an angle that is formed between the main surface 1a and a tangent line drawn from a contact point of the second chamfered portion 3b with the first chamfered portion 3a”.

FIG. 2B illustrates an example in which the first chamfered portion 3a is formed of a curved surface and the second chamfered portion 3b is formed of an inclined surface. In this case, the first inclined angle θ1 about the first chamfered portion 3a can be defined as “an angle that is formed by the main surface 1a and a tangent line drawn from a contact point of the first chamfered portion with the main surface 1a”.

FIG. 2C illustrates an example in which both the first chamfered portion 3a and the second chamfered portion 3b are formed by a curved surface. In this case, the first inclined angle θ1 about the first chamfered portion 3a and the second inclined angle θ2 about the second chamfered portion 3b may be defined in the same manner as in FIGS. 2A and 2B. In any of the examples of FIGS. 2A, 2B, and 2C, the second inclined angle θ2 is larger than the first inclined angle θ1 as in the example of FIG. 1.

Although the chamfered portion 3 is formed only on a front surface side of the substrate 1 in the example illustrated in FIGS. 1, 2A, 2B, and 2C, the same chamfered portion 3 may be formed on a back surface side of the substrate 1. In the following description, a shape of the chamfered portion 3 is the same shape as that illustrated in FIG. 1 unless otherwise specified.

### Substrate Manufacturing Method

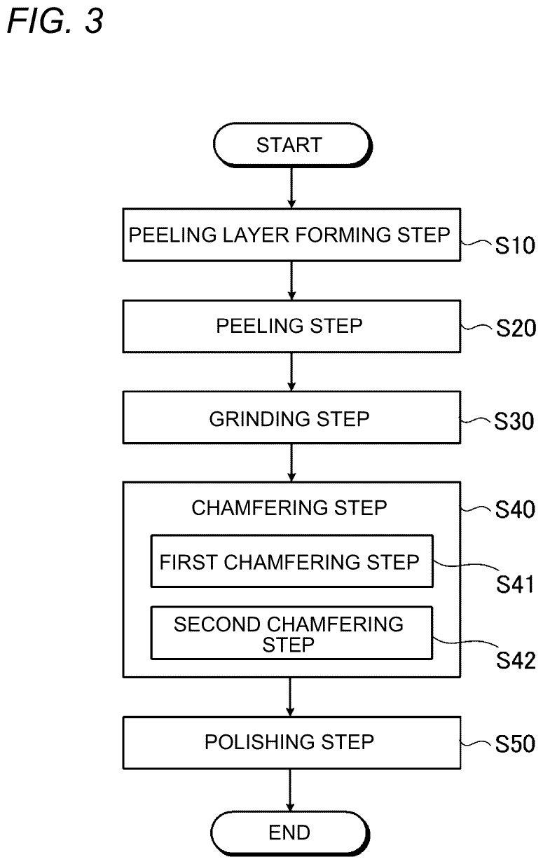

Next, a substrate manufacturing method will be described. Here, for the manufacturing method of the chamfered substrate 1 described above, a series of processing including chamfering processing from the peeling of the substrate 1 from the ingot 100 to the polishing of the peeled substrate 1 will be described. FIG. 3 is a flowchart illustrating an example of the manufacturing method of the substrate 1. The manufacturing method of the substrate 1 in the embodiment includes, as processing, a peeling layer forming step S10, a peeling step S20, a grinding step S30, a chamfering step S40, and a polishing step S50. The chamfering step S40 includes a first chamfering step S41 of forming the first chamfered portion 3a and a second chamfering step S42 of forming the second chamfered portion 3b.

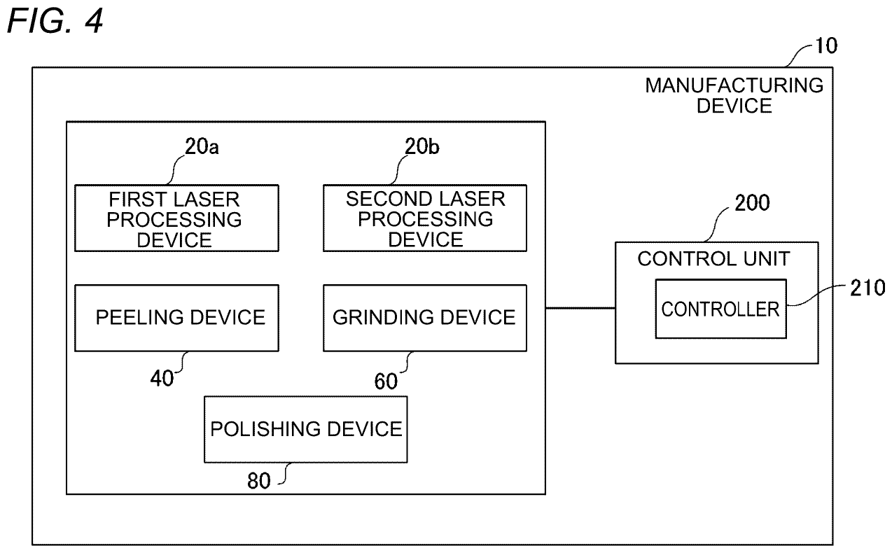

In the substrate manufacturing method, the processing of each step is executed using the manufacturing device 10 of the substrate 1 (hereinafter, referred to as the “manufacturing device 10”). FIG. 4 is a block diagram illustrating an example of the manufacturing device 10. The manufacturing device 10 includes the first laser processing device 20a, the second laser processing device 20b, the peeling device 40, a grinding device 60, and the polishing device 80, and performs processing of each step using these devices. Specifically, the peeling layer forming step S10 is performed by the first laser processing device 20a, the peeling step S20 is performed by the peeling device 40, the grinding step S30 is performed by the grinding device 60, the chamfering step S40 is performed by the second laser processing device 20b, and the polishing step S50 is performed by the polishing device 80. Therefore, hereinafter, the first laser processing device 20a, the second laser processing device 20b, the peeling device 40, the grinding device 60, and the polishing device 80 will be described together with the description of each step.

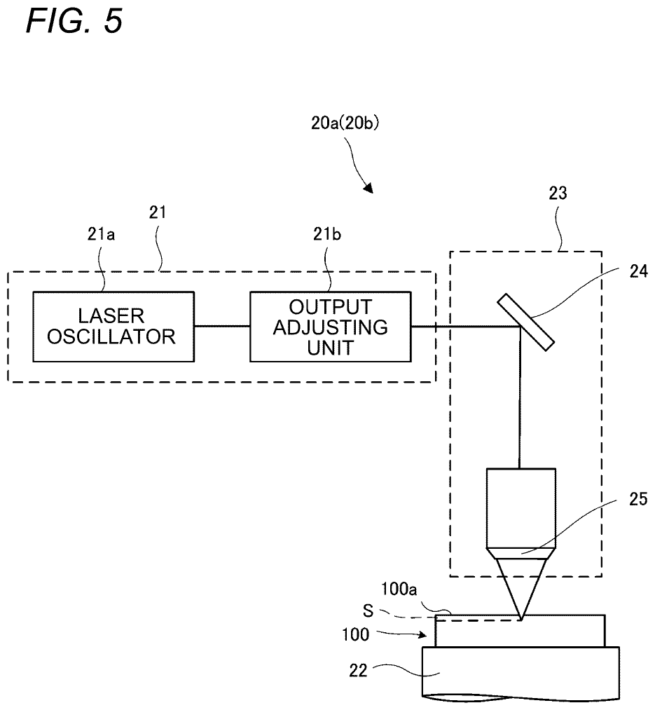

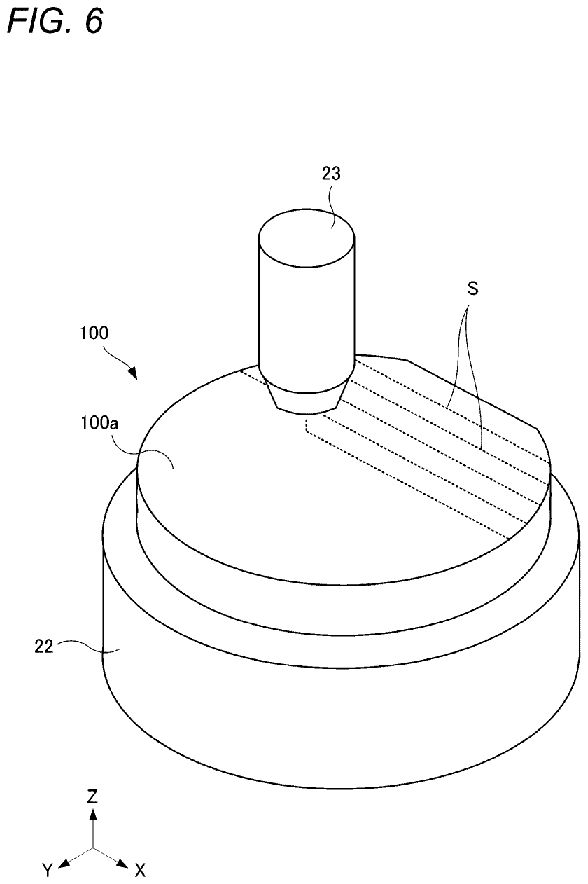

In the manufacturing device 10, for example, the first laser processing device 20a, the second laser processing device 20b, the peeling device 40, the grinding device 60, and the polishing device 80 may be integrally mounted on a common base, or at least one device may be separately mounted on another base. The first laser processing device 20a and the second laser processing device 20b may have the same configuration, and therefore, here, the configuration of the first laser processing device 20a will be representatively described, and the description of the configuration of the second laser processing device 20b will be omitted. Although the first laser processing device 20a will be described with reference to FIGS. 5 and 6, it is assumed that each component illustrated in FIGS. 5 and 6 is common to the first laser processing device 20a and the second laser processing device 20b.

The manufacturing device 10 is provided with a control unit 200 that controls each of the devices. The control unit 200 is, for example, a known computer including a controller 210 that performs various calculations, a storage unit having a storage medium, and an input and output interface that controls input and output of data between the inside and outside of the control unit (all not illustrated). The controller 210 executes various programs stored in the storage unit. For example, the controller 210 executes each processing of the flowchart illustrated in FIG. 3 as an example of a program for improving the polishing rate when polishing the substrate 1 in the manufacturing process of the substrate 1 in the manufacturing device 10.

### Peeling Layer Forming Step

The peeling layer forming step S10 is a step of forming a peeling layer S inside the ingot 100 performed by the first laser processing device 20a. Here, the first laser processing device 20a will be described.

FIG. 5 is a schematic view of the first laser processing device 20a. The first laser processing device 20a includes a laser beam irradiation unit 21 for applying a laser beam and a first holding table 22 for suction-holding the substrate 1 to be laser-processed.

The laser beam irradiation unit 21 includes a laser oscillator 21a that oscillates a YAG laser or a YVO4 laser, and an output adjusting unit 21b. Although not particularly illustrated, the laser oscillator 21a has a Brewster window, and the laser beam emitted from the laser oscillator 21a is a linearly polarized laser beam.

The laser beam adjusted to predetermined power by the output adjusting unit 21b of the laser beam irradiation unit 21 is reflected by a mirror 24 of a condenser 23, and then a condenser point is positioned inside the ingot 100, which is a workpiece held on the first holding table 22, by a condenser lens 25, and the laser beam is applied. The condenser 23 may be provided with an up-down movement unit UD (not illustrated). The up-down movement unit UD is implemented to be able to move the position of condenser lens 25 in an up-down direction. By controlling the up-down movement unit UD, the condenser point of the laser beam emitted from the laser oscillator 21a can be moved inside the ingot 100.

The ingot 100 is, for example, a SiC single crystal ingot or a GaN single crystal ingot. The ingot 100 is not limited to the single crystal ingot and may be a polycrystalline ingot.

FIG. 6 is a diagram illustrating a state in which a laser beam is applied by the condenser 23 from the front surface 100a of the ingot 100. As illustrated in FIGS. 5 and 6, the first laser processing device 20a applies a laser beam to the front surface 100a of the ingot 100 to form the peeling layer S inside the ingot 100. Since the peeling layer S is formed inside the ingot 100, the peeling layer S normally does not appear on the front surface 100a of the ingot 100, and in the example of FIG. 6, the peeling layer S is indicated by a broken line for convenience of description.

Using the first laser processing device 20a implemented as described above, in the peeling layer forming step S10, the controller 210 applies a laser beam having a wavelength that transmits through the ingot 100 to the front surface 100a of the ingot 100 with respect to the ingot 100 held by the first holding table 22, and positions the condenser point of the laser beam at a position deeper than the front surface 100a of the ingot 100 to form the peeling layer S. For example, the controller 210 forms the peeling layer S by positioning the condenser point of the laser beam at a depth corresponding to a target thickness of the substrate 1. Then, as illustrated in FIG. 6, the controller 210 processes and feeds the ingot 100 so that the condenser point moves from one end side to the other end side of the ingot 100 along the X-axis direction, forming the peeling layer S along the X-axis direction, and then indexes and feeds the ingot 100 a predetermined amount in the Y-axis direction, and then processes and feeds the ingot 100 so that the condenser point moves from the other end side to the one end side of the ingot 100 along the X-axis direction, repeating the processing of forming the peeling layer S along the X-axis direction. Accordingly, the peeling layer S including cracks is formed inside the ingot 100.

### Peeling Step

Next, the peeling step S20 will be described. The peeling step S20 is a step of peeling the substrate 1 from the ingot 100 by the peeling device 40. Here, the peeling device 40 will be described.

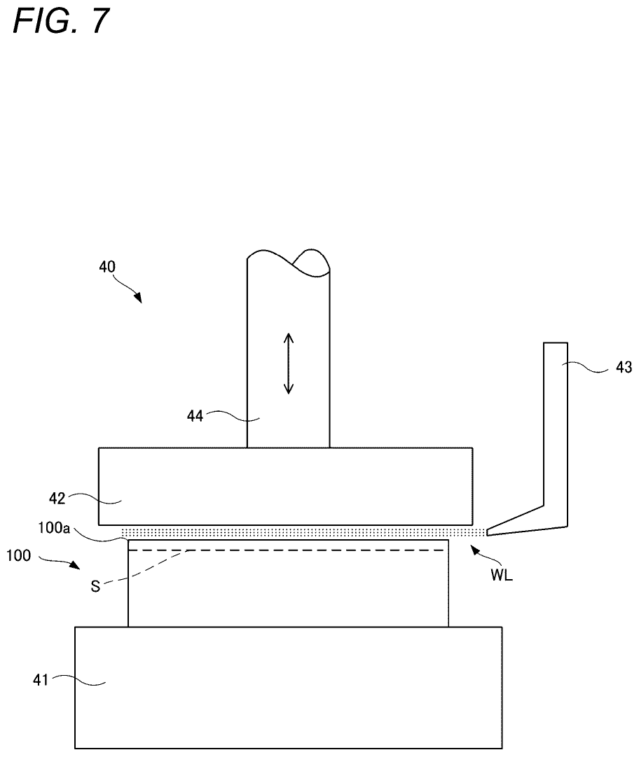

FIG. 7 is a schematic view illustrating the peeling device 40. As illustrated in FIG. 7, the peeling device 40 includes an ultrasonic vibrator 42 that is provided to face the front surface 100a of the ingot 100 held by a second holding table 41 and applies ultrasonic waves to the ingot 100, a liquid supply nozzle 43 that supplies a liquid (for example, pure water) between the front surface 100a of the ingot 100 and the ultrasonic vibrator 42, and a vibrator lifting mechanism 44 that adjusts a position of the ultrasonic vibrator 42 in the up-down direction.

The ultrasonic vibrator 42 is positioned by the vibrator lifting mechanism 44 at a position where a small gap is provided between the ultrasonic vibrator 42 and the front surface 100a of the ingot 100. While the ultrasonic waves are being applied to the ingot 100, the liquid supply nozzle 43 continuously supplies the liquid to the gap between the ultrasonic vibrator 42 and the front surface 100a of the ingot 100 to form a liquid layer WL. The ultrasonic waves emitted from the ultrasonic vibrator 42 are transmitted to the ingot 100 via the liquid layer WL to extend the cracks at the peeling layer S formed in the ingot 100. Accordingly, a strength of the peeling layer S decreases. Further, the ultrasonic wave is applied to the front surface 100a of the ingot 100, and then the front surface 100a of the ingot 100 is sucked by a suction pad (not illustrated) and the suction pad is moved upward, so that a thin plate including the front surface 100a of the ingot 100 can be peeled off as the substrate 1 from the peeling layer S as a starting point.

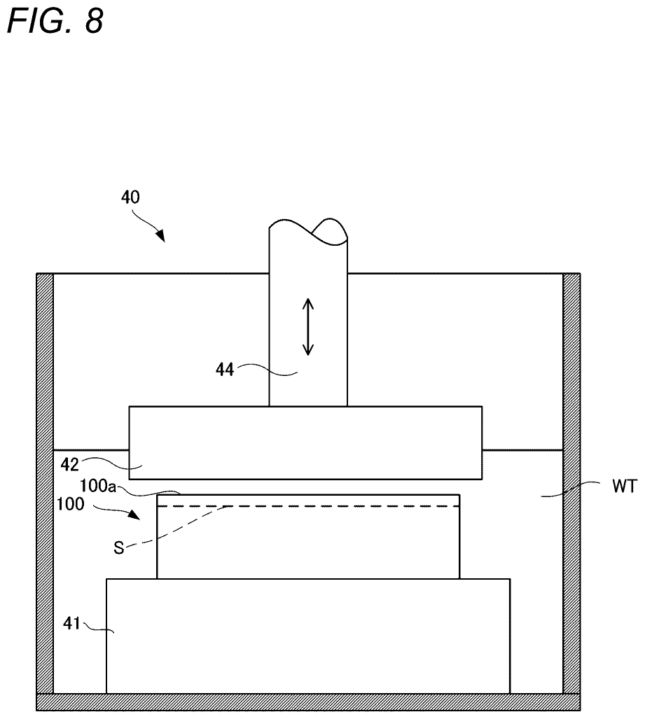

A configuration of the peeling device 40 is not limited to the configuration illustrated in FIG. 7, and may be, for example, a configuration illustrated in FIG. 8. FIG. 8 is a diagram illustrating the peeling device 40 according to a modification. The peeling device 40 in the modification has a water tank WT in which a liquid is stored, and the ultrasonic vibrator 42 and the ingot 100 are placed in the liquid. That is, the ultrasonic waves emitted from the ultrasonic vibrator 42 are applied to the ingot 100 via the liquid stored in the water tank WT. With such a configuration, the substrate 1 can also be peeled from the ingot 100 with the peeling layer S as a starting point.

Using the peeling device 40 implemented as described above, in the peeling step S20, the controller 210 peels off the thin plate including the front surface 100a of the ingot 100 as the substrate 1 with the peeling layer S as a starting point. Specifically, the controller 210 applies an ultrasonic wave vibration from the ultrasonic vibrator 42 to the ingot 100. The ultrasonic waves emitted from the ultrasonic vibrator 42 are transmitted to the ingot 100 via the liquid layer WL to extend the cracks at the peeling layer S formed in the ingot 100. Accordingly, the strength of the peeling layer S decreases, the ingot 100 is broken starting from the peeling layer S, and an upper side of the ingot 100 is peeled as the substrate 1.

### Grinding Step

Next, the grinding step S30 will be described. The grinding step S30 is a step of planarizing a peeling surface of the substrate 1 peeled in the peeling step S20 performed by the grinding device 60. Here, the grinding device 60 will be described.

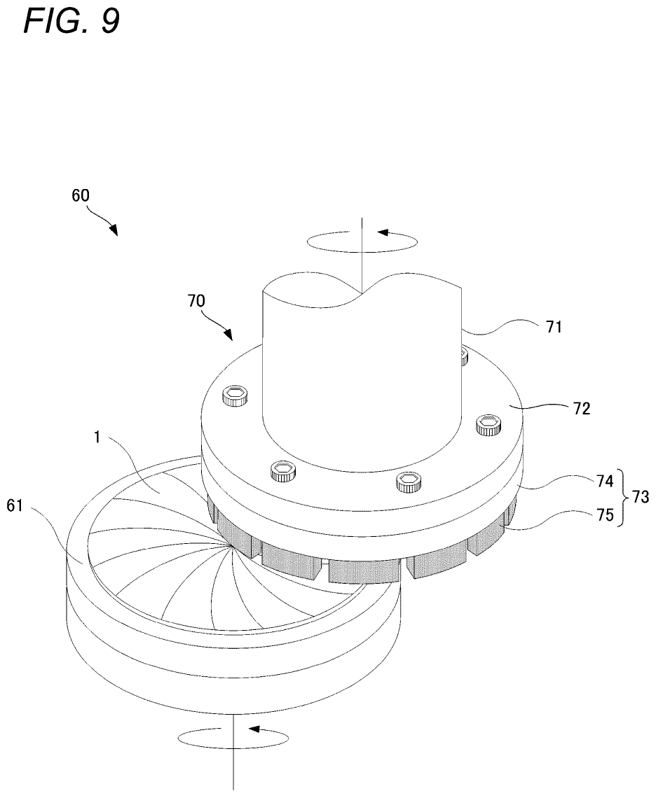

FIG. 9 is a perspective diagram illustrating the grinding device 60. The grinding device 60 includes a third holding table 61 that sucks and holds the substrate 1 to be ground, and a grinding unit 70 that grinds the substrate 1 sucked and held by the third holding table 61. The third holding table 61 is coupled to a rotation drive source (not illustrated) such as a motor, and is rotatable about a rotation axis perpendicular to a holding surface by operating the rotation drive source.

The grinding unit 70 provided above the third holding table 61 includes a spindle 71 substantially perpendicular to the third holding table 61 and a rotation drive source (not illustrated) such as a motor for rotating the spindle 71. A disk-shaped wheel mount 72 is fixed to a lower end of the spindle 71, and a grinding wheel 73 is fixed to a lower end of the wheel mount 72.

The grinding wheel 73 has a circular base 74 made of a metal material such as stainless steel or aluminum, and a plurality of grinding stones 75 arranged in a circular pattern on a lower surface of the base 74. The grinding stones 75 contain a binder formed of ceramics, resin, a metal material, and the like, and numerous abrasive grains such as diamond dispersed and fixed in the binder.

In the grinding device 60 implemented as described above, in the grinding step S30, the controller 210 adjusts a positional relation between the third holding table 61 and the grinding unit 70 such that a center of the substrate 1 held by the third holding table 61 coincides with tracks of the grinding stones. Then, while rotating the third holding table 61 and the grinding wheel 73, the grinding wheel 73 is lowered along a processing-feed direction (vertical direction) parallel to a rotation axis of the spindle 71, and lower surfaces of the grinding stones 75 are brought into contact with the substrate 1 held under suction on the third holding table 61, thereby starting grinding of the substrate 1. As the grinding of the substrate 1 proceeds, the peeling layer S is removed and the substrate 1 can be planarized.

### Chamfering Step

Next, the chamfering step S40 will be described. The chamfering step S40 is a step of forming the chamfered portion 3 on the outer peripheral portion 2 of the substrate 1. The chamfering step S40 includes the first chamfering step S41 of forming the first chamfered portion 3a and the second chamfering step S42 of forming the second chamfered portion 3b, and the processing of the chamfering step S40 can be performed by the second laser processing device 20b. As described above, the configuration of the second laser processing device 20b may be similar to that of the first laser processing device 20a.

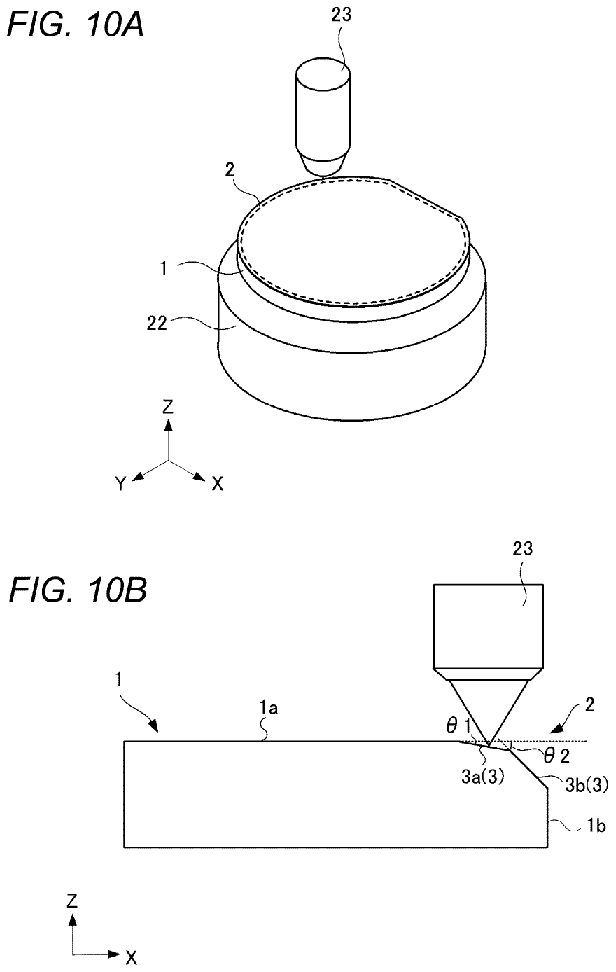

In the first chamfering step S41, the controller 210 forms the first chamfered portion 3a by positioning the condenser point of the laser beam on the outer peripheral portion 2 of the substrate 1 held by the first holding table 22 and applying the laser beam. FIG. 10A is a diagram illustrating a state in which chamfering is performed by applying a laser beam by the condenser 23 in the second laser processing device 20b, and FIG. 10B is a front view thereof. For example, as illustrated in FIGS. 10A and 10B, the laser beam may be applied from the vertical direction of the substrate 1. The first holding table 22 is implemented to be rotatable about the Z axis and to be movable in each of the X-axis direction and the Y-axis direction.

More specifically, in the first chamfering step S41, first, the substrate 1 is sucked and held by the first holding table 22. Next, the substrate 1 is imaged by an imaging unit (not illustrated) provided in the second laser processing device 20b, and a positional relation between the substrate 1 and the condenser 23 is adjusted based on a captured image. Next, the condenser point is positioned at the outer peripheral portion 2 of the substrate 1.

Next, while rotating the first holding table 22 at a predetermined speed, a laser beam having a wavelength that absorbs the substrate 1 is applied along an outer peripheral edge indicated by a broken line. As described above, since the first holding table 22 is movable in the X-axis direction and the Y-axis direction, the holding table is moved in an appropriate direction to move the condenser point. In this manner, the first chamfered portion 3a is formed by irradiating the entire circumference of the outer peripheral portion 2 of the substrate 1 with the laser beam.

The chamfering by the second laser processing device 20b can correspond to various shapes by controlling an irradiation time of the laser beam, a laser output, a processing feed speed, and the like. For example, as described above, since the first inclined angle θ1 in the first chamfered portion 3a is an angle relatively smaller than the second inclined angle θ2 of the second chamfered portion 3b, in this case, a relatively small inclined angle can be formed by shortening the irradiation time, reducing the laser output, increasing the processing feed speed, or the like, as compared with the case of forming the second chamfered portion 3b to be described later.

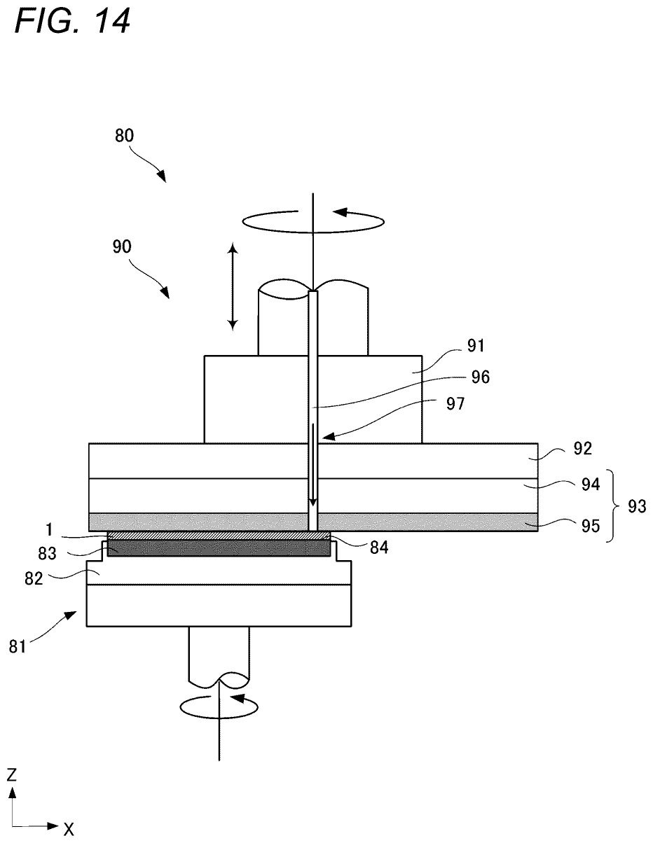

As described above, the first inclined angle θ1 of the first chamfered portion 3a is set to an angle capable of improving the polishing rate. In general, between a case in which the hardness of the polishing pad 95 in the polishing device 80 (see FIG. 14) is high and a case in which the hardness of the polishing pad 95 is low, the polishing rate is relatively high when the hardness of the polishing pad 95 is high, and the polishing rate is relatively low when the hardness of the polishing pad 95 is low. Therefore, in order to improve the polishing rate, it is preferable to use the polishing pad 95 having high hardness. On the other hand, when the hardness of the polishing pad 95 is increased, the polishing pad 95 does not conform to the shape of the chamfered portion 3 of the outer peripheral portion 2 to be chamfered in the polishing of the substrate 1, so that the polishing at the outer peripheral portion 2 to be chamfered is dominant from the main surface 1a side of the substrate 1, the polishing rate of the main surface 1a is low, and the polishing rate may vary in the entire substrate. Therefore, the first inclined angle θ1 of the first chamfered portion 3a in contact with the main surface 1a is preferably set according to the hardness of the polishing pad 95. The first inclined angle θ1 is preferably set to an angle that increases the polishing rate.

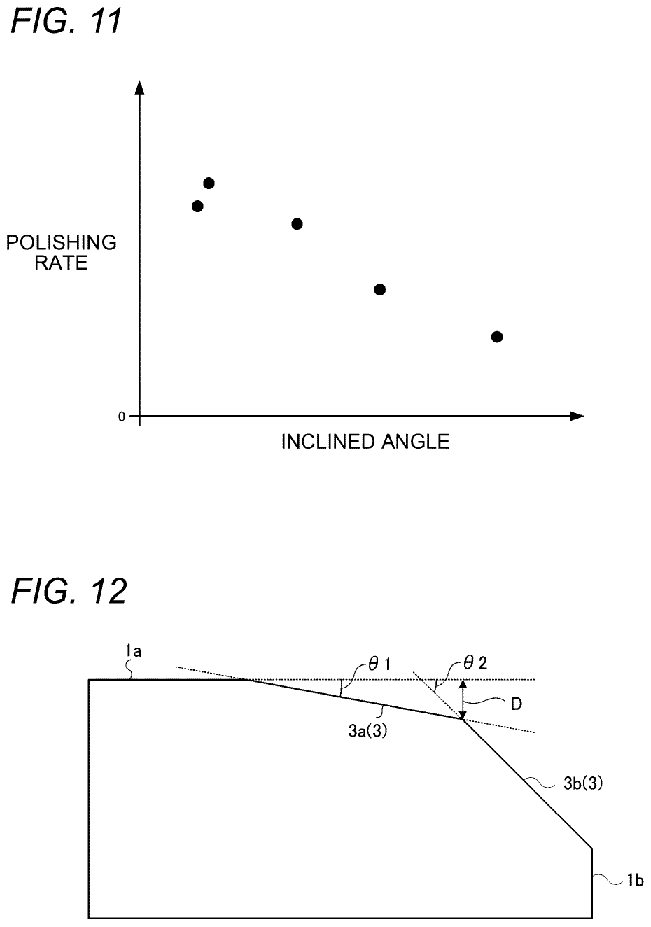

FIG. 11 is a diagram illustrating the relation between the inclined angle and the polishing rate. As can be understood from FIG. 11, when the inclined angle of the chamfered portion 3 is relatively small, the polishing pad 95 has an optimum inclined angle along the chamfered portion 3, and the polishing rate is high. That is, in order to improve the polishing rate, when the hardness of the polishing pad 95 is high, the first inclined angle θ1 of the first chamfered portion 3a is preferably small. In the embodiment, for example, the chamfering is performed by setting the first inclined angle θ1 to about “10° to 20°”.

A distance D of the first chamfered portion 3a from the main surface 1a in a thickness direction of the substrate 1 (hereinafter, also referred to as a “distance D in the thickness direction of the substrate 1”) may change according to the first inclined angle θ1 of the first chamfered portion 3a. In this regard, the distance D in the thickness direction of the substrate 1 is a distance when a perpendicular line is drawn from the main surface 1a to a contact point between the first chamfered portion 3a and the second chamfered portion 3b (or a height position corresponding to the contact point) in the first chamfered portion 3a. FIG. 12 is an enlarged diagram of the vicinity of the chamfered portion 3 as a diagram illustrating an example of the distance D. The distance D in the thickness direction of the substrate 1 increases as the first inclined angle θ1 increases, and decreases as the first inclined angle θ1 decreases.

On the other hand, since the polishing pad 95 used in the polishing step S50 to be described later sinks in the thickness direction of the substrate 1 by polishing the substrate 1, the distance D of the first chamfered portion 3a from the main surface 1a in the thickness direction of the substrate 1 is preferably set according to a sinking amount of the polishing pad 95. Specifically, the distance D in the thickness direction of the substrate 1 is preferably larger than the sinking amount of the polishing pad 95. In other words, the first inclined angle θ1 is preferably set such that the distance D in the thickness direction of the substrate 1 is larger than the sinking amount of the polishing pad 95.

The distance D in the thickness direction of the substrate 1 is preferably slightly larger than the sinking amount of the polishing pad 95. Accordingly, it is possible to make the distance D in the thickness direction of the substrate 1 larger than the sinking amount of the polishing pad 95 while reducing a time required for processing the first chamfered portion 3a.

Here, a method for obtaining the sinking amount of the polishing pad 95 will be described. In the embodiment, the hardness (Asker-C) of the polishing pad 95 is, for example, 55 degree to 90 degrees, and a compression rate of the polishing pad 95 is 2% to 15%. A range of the compression rate is due to that an edge of the substrate 1 is chipped when the compression rate of the polishing pad 95 is 2% or more, and a high polishing rate cannot be obtained when the compression rate of the polishing pad 95 is 15% or more. The hardness of the polishing pad 95 is the hardness of a general polishing pad.

When the compression rate of the polishing pad 95 is C, the following equation is established.

Compression Rate C=(t1−T2)/t1 Equation (1)

Here, T1 and T2 are thicknesses of the polishing pad 95 under a predetermined compressive load, for example, T1 is a pad thickness under a compressive load W1 [g/cm²], and T2 is a pad thickness [μm] under a compressive load W2 [g/cm²].

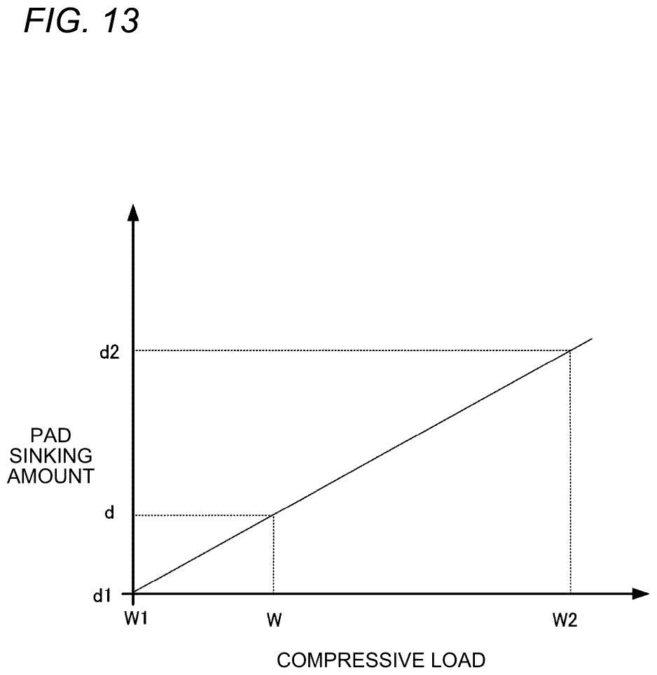

When the sinking amount of the polishing pad 95 when a compressive load W1 is d1 [μm] and the sinking amount of the polishing pad 95 when the compressive load W2 is d2 [μm], a relation as illustrated in FIG. 13 is established.

In this case, for example, when the sinking amount of the polishing pad 95 at any compressive load W is d [μm], the sinking amount d of the polishing pad 95 can be represented by the following general expression based on the relation between the sinking amount d1 of the polishing pad 95 at the compressive load W1 and the sinking amount d2 of the polishing pad 95 at the compressive load W2.

d=((d2−d1)/(W2−W1)×(W−W1) Equation (2)

When Equation (2) is expanded based on the relations of T1, T2, and Equation (1) described above,

d=((T1−T2)/(W2−W1)×(W−W1) Equation (3)

=((C·T1/(W2−W1)×(W−W1) Equation (4)

can be obtained.

The control unit 200 records, for example, these relational expressions in a storage unit in advance. The controller 210 can calculate the sinking amount d of the polishing pad 95 according to various conditions of the polishing pad 95 and the like with reference to the storage unit. Then, the controller 210 sets the first inclined angle θ1 so that the distance D in the thickness direction of the substrate 1 is a value slightly larger than the sinking amount d of the polishing pad 95, and performs the first chamfering step S41 so that the distance D is the first inclined angle θ1.

In the second chamfering step S42, the controller 210 forms the second chamfered portion 3b using the second laser processing device 20b by the same method as in the first chamfering step S41. That is, the second chamfered portion 3b is formed by irradiating the outer peripheral edge of the substrate 1 with a laser beam having a wavelength that absorbs the substrate 1 while rotating the first holding table 22 at a predetermined speed. In the second chamfering step S42, the controller 210 positions the condenser point of the laser beam on the outer peripheral portion 2 of the substrate 1 held by the first holding table 22 and applies the laser beam. At this time, the first holding table 22 is appropriately moved in the X-axis direction and the Y-axis direction to move the condenser point. In this manner, the second chamfered portion 3b is formed by irradiating the entire circumference of the outer peripheral portion 2 of the substrate 1 with the laser beam.

The second inclined angle θ2 of the second chamfered portion 3b is larger than the first inclined angle θ1 as described above. The second inclined angle θ2 is set to, for example, an angle at which the outer peripheral sag and the edge chipping in the outer peripheral portion 2 during polishing can be reduced while satisfying the SEMI standard. The angle may be, for example, 45°. Therefore, the controller 210 forms the desired second chamfered portion 3b by controlling the irradiation time of the laser beam, the laser output, the processing feed speed, and the like.

The order of the first chamfering step S41 and the second chamfering step S42 may be reversed, that is, the first chamfering step S41 may be performed after the second chamfering step S42 is performed. The controller 210 may also execute the same processing of the chamfering step S40 on the back surface side of the substrate 1.

### Polishing Step

Next, the polishing step S50 will be described. The polishing step S50 is a step of mirror-finishing the planarized substrate 1 by the polishing device 80. Here, the polishing device 80 will be described.

FIG. 14 is a schematic view illustrating the polishing device 80. The polishing device 80 includes a fourth holding table 81 that sucks and holds the substrate 1, and a polishing unit 90 that polishes the substrate 1 held by the fourth holding table 81.

The fourth holding table 81 is implemented to be rotatable about the Z axis. The fourth holding table 81 has a disk-shaped frame body 82 formed of non-porous ceramics. A disk-shaped concave portion is formed in a central portion of the frame body 82 in a radial direction, and a porous plate 83 formed of porous ceramics is fixed to the concave portion. An upper surface of the porous plate 83 constitutes a holding surface 84 that sucks and holds the substrate 1.

The polishing unit 90 is disposed above the fourth holding table 81. The polishing unit 90 has a cylindrical spindle housing (not illustrated) disposed substantially parallel to the Z-axis direction. A columnar spindle 91 disposed along the Z-axis direction is rotatably accommodated in a spindle housing. A rotation drive source (not illustrated) such as a motor for rotating the spindle 91 is provided in the vicinity of an upper end portion of the spindle 91.

A disk-shaped mount 92 is coupled to a lower end portion of the spindle 91. The mount 92 has a diameter larger than the diameter of the holding surface 84. A disk-shaped polishing tool 93 having substantially the same diameter as the mount 92 is mounted on a lower surface of the mount 92 via a fixing member such as a bolt.

The polishing tool 93 includes a disk-shaped platen 94 coupled to the lower surface of the mount 92. The platen 94 is formed of a hard resin and has substantially the same diameter as the mount 92. A disk-shaped polishing pad 95 is fixed to a lower surface side of the platen 94.

The polishing pad 95 is made of, for example, hard foamed polyurethane, and may have a nonwoven fabric instead of the hard foamed polyurethane. When the substrate 1 is polished by the polishing pad 95, the substrate 1 is polished using a slurry containing free abrasive grains.

The polishing tool 93 is disposed concentrically with the spindle 91 and the mount 92. A through hole 96 penetrating the polishing pad 95, the platen 94, the mount 92, and the spindle 91 is formed in a central portion of the polishing tool 93 in the radial direction. A slurry supply source (not illustrated) is coupled to an upper end portion of the through hole 96. The through hole 96 functions as a slurry supply path 97 for supplying slurry to the substrate 1 and the polishing pad 95 when the substrate 1 is polished by the polishing pad 95.

In the polishing device 80 implemented as described above, in the polishing step S50, the controller 210 sucks and holds the substrate 1 on the holding surface 84, and disposes the fourth holding table 81 below the polishing tool 93. Then, the polishing pad 95 is lowered while the spindle 91 and the fourth holding table 81 are rotated at different rotational speeds and the slurry is supplied from the slurry supply path 97 to the front surface of the substrate 1 and a lower surface of the polishing pad 95. Then, the polishing pad 95 is pressed against the substrate 1 at a predetermined pressure to press the lower surface of the polishing pad 95 against the front surface of the substrate 1. In this manner, the main surface 1a of the substrate 1 is polished. During the polishing process, for example, the polishing pad 95 may be slightly reciprocated and swung in the X-axis direction on a line connecting the center of the polishing pad 95 and the center of the substrate 1. Accordingly, the entire substrate is allowed to be polished more uniformly. In this way, the main surface 1a of the substrate 1 is polished to mirror-finish the substrate 1. The processing of the polishing step S50 may be similarly performed on the back surface of the substrate 1.

As described above, in the embodiment, the chamfered portion 3 extending in two stages including the first chamfered portion 3a and the second chamfered portion 3b is formed in the outer peripheral portion 2 of the substrate 1, and the main surface 1a and a part of the outer peripheral portion 2 in contact with the main surface 1a of the first chamfered portion 3a are polished. At this time, as described above, the first inclined angle θ1 of the first chamfered portion 3a is smaller than the second inclined angle θ2 of the second chamfered portion 3b, and is a relatively small inclined angle in consideration of the polishing rate. Therefore, it is possible to prevent the polishing of the outer peripheral portion 2 from becoming dominant over the main surface 1a of the substrate 1, and as a result, it is possible to reduce the variation in the polishing rate between the main surface 1a and the outer peripheral portion 2, and to improve the polishing rate of the entire substrate.

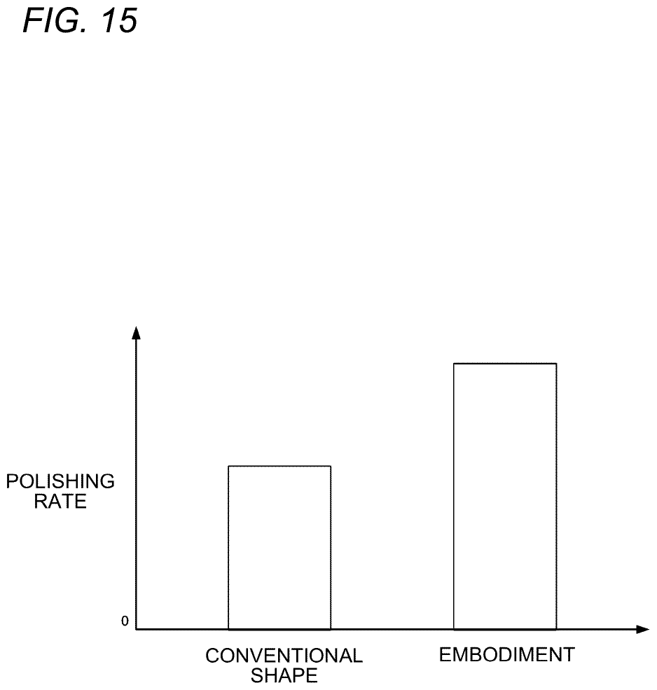

For example, as a shape for reducing the edge chipping, the polishing rate can be improved as compared with a conventional shape in which a single-stage chamfered portion having an inclined angle set to 45° is formed. FIG. 15 is a diagram in which the polishing rates of the conventional shape and the shape in the embodiment are compared, and illustrates an example in which measurement is performed under the same conditions using the same substrate except for the chamfering shape. As can be understood from FIG. 15, in the embodiment, the polishing rate can be improved by about 1.5 times as compared with the conventional shape.

In the embodiment, as described above, since the first inclined angle θ1 in the first chamfered portion 3a is a relatively small angle, and the second inclined angle θ2 in the second chamfered portion 3b is an angle capable of reducing the outer peripheral sag and the edge chipping of the outer peripheral portion 2 while satisfying the SEMI standard, it is possible to improve the polishing rate while achieving these conditions, demands, and the like. Then, since the first chamfered portion 3a having the relatively small first inclined angle θ1 is added based on the conventional shape, a design change is small, in other words, these effects can be achieved without significantly changing the shape from the conventional shape.

Although the embodiments of the disclosure have been described above with reference to the accompanying drawings, it is needless to say that the present disclosure is not limited to the embodiments. It is obvious that those skilled in the art may come up with various changes or modifications within the scope of the claims, and it is understood that these naturally fall within the technical scope of the disclosure. In addition, components in the embodiments described above may be freely combined without departing from the gist of the disclosure.

For example, in the above-described embodiment, the chamfering step S40 is implemented to be executed after the grinding step S30 and before the polishing step S50 described later, and the chamfering step S40 may be executed at least before the polishing step S50.

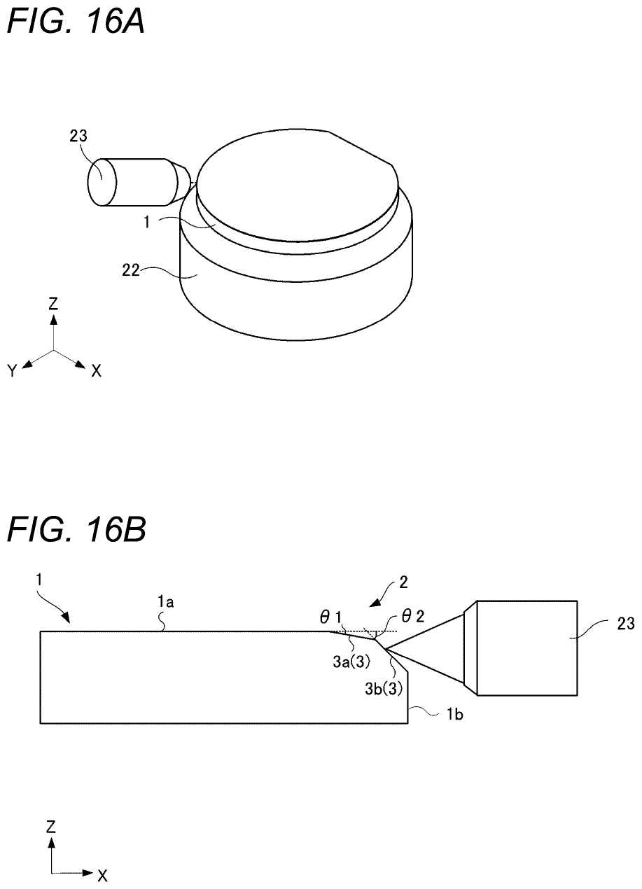

In addition, in the chamfering step S40, in the example illustrated in FIGS. 10A and 10B, the chamfered portion 3 is formed by irradiating the substrate 1 with the laser beam from the vertical direction, and the laser beam may be emitted from a horizontal direction parallel to the substrate 1, for example, as illustrated in FIGS. 16A and 16B, in addition to the vertical direction of the substrate 1. Alternatively, the angle of the substrate 1 and the laser beam may be emitted from a predetermined angle such as 45°.

As described above, the shape of the chamfered portion 3 may be the chamfered portion 3 in which a curved surface is formed on at least one of the first chamfered portion 3a or the second chamfered portion 3b, as illustrated in FIG. 2.

In the above-described embodiment, it is described that the distance D in the thickness direction of the substrate 1 is preferably a value slightly larger than the sinking amount of the polishing pad 95, and the distance D in the thickness direction may be, for example, a value in consideration of a predetermined margin with respect to the sinking amount of the polishing pad 95.

In the above-described embodiment, when the substrate 1 is manufactured from the ingot 100, the peeling layer S is formed inside the ingot 100 by using the laser beam, and the thin plate is peeled from the ingot 100 as the substrate 1 with the peeling layer S as a starting point. Meanwhile, the method for cutting out the substrate 1 from the ingot 100 is not limited to the laser beam method, and the substrate 1 may be cut out and manufactured by using a wire saw as conventionally known.

The substrate manufacturing method described in the above embodiment can be implemented by executing a control program prepared in advance by a computer. The control program is recorded in a computer-readable storage medium and executed by being read from the storage medium. The control program may be provided in a form stored in a non-transitory storage medium such as a flash memory, or may be provided via a network such as the Internet. The computer that executes the control program may be included in a device, may be included in an electronic device such as a smartphone, a tablet terminal, or a personal computer capable of communicating with the device, or may be included in a server device capable of communicating with the device and the electronic device.

The present specification describes at least the following matters. The components in parentheses correspond to those in the embodiment described above, but are not limited thereto.

(1) A manufacturing method of a substrate (substrate 1) having a main surface (main surface 1a) and a side surface (side surface 1b), the substrate manufacturing method includes:
a chamfering step (chamfering step S40) of chamfering an outer peripheral portion (outer peripheral portion 2) of the substrate, which is a boundary between the main surface and the side surface, so as to form at least one of an inclined surface or a curved surface; and
a polishing step (polishing step S50) of polishing the main surface, in which
the chamfering step includes
a first chamfering step (first chamfering step S41) of forming, at the outer peripheral portion of the substrate, a first chamfered portion (first chamfered portion 3a) by forming an inclined surface so that the inclined surface is in contact with the main surface and makes a first inclined angle (first inclined angle θ1) relative to the main surface, or by forming a curved surface so that the curved surface is in contact with the main surface and that an angle between the main surface and a tangent line drawn from a contact point between the curved surface and the main surface is a first inclined angle, and
a second chamfering step (second chamfering step S42) of forming a second chamfered portion (second chamfered portion 3b) by forming an inclined surface so that the inclined surface is in contact with the first chamfered portion and the side surface and makes, relative to the main surface, a second inclined angle (second inclined angle θ2) larger than the first inclined angle, or by forming a curved surface so that the curved surface is in contact with the first chamfered portion and the side surface and that an angle between the main surface and a tangent line drawn from a contact point between the curved surface and the first chamfered portion is a second inclined angle larger than the first inclined angle.

According to (1), the inclined angle of the first chamfered portion in contact with the main surface can be made to be a relatively small angle. Therefore, it is possible to prevent the polishing of the outer peripheral portion of the substrate from becoming dominant, and as a result, it is possible to reduce the variation in the polishing rate between the main surface and the outer peripheral portion, and to improve the polishing rate of the entire substrate. In addition, since the second chamfered portion is not in contact with the main surface and is not affected by the polishing rate, the second chamfered portion can be set to any angle, and thus can be set to a desired inclined angle capable of reducing edge chipping or the like while conforming to the standard. That is, the polishing rate of the entire chamfered portion can be improved, and a desired chamfering shape can be achieved.

(2) The substrate manufacturing method according to (1), in which
in the chamfering step, the first inclined angle is set according to hardness of a polishing pad (polishing pad 95) to be used in the polishing step.

According to (2), the polishing rate can be improved by setting the first inclined angle according to the hardness of the polishing pad.

(3) The substrate manufacturing method according to (2), in which
the first inclined angle is smaller as the hardness of the polishing pad is higher.

According to (3), the higher the hardness of the polishing pad, the higher the polishing rate, in other words, the more easily the polishing of the chamfered portion proceeds. Therefore, by setting the first inclined angle to be smaller as the hardness of the polishing pad is higher, progress of polishing of the outer peripheral portion relative to the main surface can be prevented, and as a result, a variation in polishing rate between the main surface and the outer peripheral portion can be reduced, and the polishing rate of the entire substrate can be improved.

(4) The substrate manufacturing method according to (1) or (2), in which
in the chamfering step, a distance, in a thickness direction of the substrate (a distance D in the thickness direction of the substrate), from the main surface to an end part of the first chamfered portion in contact with the second chamfered portion is set according to a sinking amount of the polishing pad (polishing pad 95) with respect to the main surface when polishing is performed in the polishing step.

According to (4), the distance in the thickness direction of the substrate from the main surface to the end part of the first chamfered portion in contact with the second chamfered portion can be set to an appropriate distance according to the sinking amount of the polishing pad, and as a result, the polishing rate can be improved.

(5) The substrate manufacturing method according to (4), in which
the distance in the thickness direction is larger than the sinking amount of the polishing pad.

According to (5), since the distance in the thickness direction of the substrate is larger than the sinking amount of the polishing pad, the polishing pad can be prevented from coming into contact with the inclined surface or the curved surface of the first chamfered portion, and the main surface can be appropriately polished.

(6) A substrate (substrate 1) having a main surface (main surface 1a) and a side surface (side surface 1b), includes:
a chamfered portion (chamfered portion 3) having at least one of an inclined surface or a curved surface formed on an outer peripheral portion (outer peripheral portion 2) of the substrate, which is a boundary between the main surface and the side surface, in which
the chamfered portion includes
a first chamfered portion (first chamfered portion 3a) configured to form, at the outer peripheral portion of the substrate, an inclined surface so that the inclined surface is in contact with the main surface and makes a first inclined angle (first inclined angle θ1) relative to the main surface, or form a curved surface so that the curved surface is in contact with the main surface and that an angle between the main surface and a tangent line drawn from a contact point between the curved surface and the main surface is a first inclined angle, and
a second chamfered portion (second chamfered portion 3b) configured to form an inclined surface so that the inclined surface is in contact with the first chamfered portion and the side surface and makes, relative to the main surface, a second inclined angle (second inclined angle θ2) larger than the first inclined angle, or form a curved surface so that the curved surface is in contact with the first chamfered portion and the side surface and that an angle between the main surface and a tangent line drawn from a contact point between the curved surface and the first chamfered portion is a second inclined angle larger than the first inclined angle.

According to (6), the inclined angle of the first chamfered portion in contact with the main surface can be made to be a relatively small angle. Therefore, it is possible to prevent the polishing of the outer peripheral portion of the substrate from becoming dominant, and as a result, it is possible to reduce the variation in the polishing rate between the main surface and the outer peripheral portion. In other words, the polishing rate of the entire substrate can be improved. In addition, since the second chamfered portion is not in contact with the main surface and is not affected by the polishing rate, the second chamfered portion can be set to any angle, and thus can be set to a desired inclined angle capable of reducing edge chipping or the like while conforming to the standard. That is, the polishing rate of the entire chamfered portion can be improved, and a desired chamfering shape can be achieved.

### REFERENCE SIGNS LIST

1 substrate
1a Main Surface
1b side surface
2 outer peripheral portion
3 chamfered portion
3a first chamfered portion
3b second chamfered portion
95 polishing pad
D distance in thickness direction of substrate
θ1 first inclined angle
θ2 second inclined angle
S40 chamfering step
S41 first chamfering step
S42 second chamfering step
S50 polishing step

What is claimed is:

1. A manufacturing method of a substrate having a main surface and a side surface, the manufacturing method comprising:
chamfering an outer peripheral portion of the substrate, which is a boundary between the main surface and the side surface, so as to form at least one of an inclined surface or a curved surface; and
polishing the main surface, wherein
the chamfering includes
forming, at the outer peripheral portion of the substrate, a first chamfered portion by forming an inclined surface so that the inclined surface is in contact with the main surface and makes a first inclined angle relative to the main surface, or by forming a curved surface so that the curved surface is in contact with the main surface and that an angle between the main surface and a tangent line drawn from a contact point between the curved surface and the main surface is a first inclined angle, and
forming a second chamfered portion by forming an inclined surface so that the inclined surface is in contact with the first chamfered portion and the side surface and makes, relative to the main surface, a second inclined angle larger than the first inclined angle, or by forming a curved surface so that the curved surface is in contact with the first chamfered portion and the side surface and that an angle between the main surface and a tangent line drawn from a contact point between the curved surface and the first chamfered portion is a second inclined angle larger than the first inclined angle.

2. The manufacturing method according to claim 1, wherein
in the chamfering, the first inclined angle is set according to hardness of a polishing pad to be used in the polishing.

3. The manufacturing method according to claim 2, wherein
the first inclined angle is smaller as the hardness of the polishing pad is higher.

4. The manufacturing method according to claim 1, wherein
in the chamfering, a distance, in a thickness direction of the substrate, from the main surface to an end part of the first chamfered portion in contact with the second chamfered portion is set according to a sinking amount of a polishing pad, to be used in the polishing, by which the polishing pad sinks with respect to the main surface when the polishing is performed.

5. The manufacturing method according to claim 2, wherein
in the chamfering, a distance, in a thickness direction of the substrate, from the main surface to an end part of the first chamfered portion in contact with the second chamfered portion is set according to a sinking amount of the polishing pad by which the polishing pad sinks with respect to the main surface when the polishing is performed.

6. The manufacturing method according to claim 4, wherein
the distance in the thickness direction is a value larger than the sinking amount of the polishing pad.

7. The manufacturing method according to claim 5, wherein
the distance in the thickness direction is a value larger than the sinking amount of the polishing pad.

8. A substrate having a main surface and a side surface, comprising:
a chamfered portion having at least one of an inclined surface or a curved surface formed on an outer peripheral portion of the substrate, which is a boundary between the main surface and the side surface, wherein
the chamfered portion includes
a first chamfered portion configured to form, at the outer peripheral portion of the substrate, an inclined surface so that the inclined surface is in contact with the main surface and makes a first inclined angle relative to the main surface, or form a curved surface so that the curved surface is in contact with the main surface and that an angle between the main surface and a tangent line drawn from a contact point between the curved surface and the main surface is a first inclined angle, and
a second chamfered portion configured to form an inclined surface so that the inclined surface is in contact with the first chamfered portion and the side surface and makes, relative to the main surface, a second inclined angle larger than the first inclined angle, or form a curved surface so that the curved surface is in contact with the first chamfered portion and the side surface and that an angle between the main surface and a tangent line drawn from a contact point between the curved surface and the first chamfered portion is a second inclined angle larger than the first inclined angle.
